(19) United States
(12) Patent Application Publication
(10) Pub. No.: US 2024/0240083 A1
(43) Pub. Date: Jul. 18, 2024

(54) ETCHING SOLUTION, METHOD OF MANUFACTURING SILICON DEVICE AND METHOD OF TREATING SUBSTRATE USING THE ETCHING SOLUTION

(71) Applicant: TOKUYAMA CORPORATION, Yamaguchi (JP)

(72) Inventors: Manami OSHIO, Yamaguchi (JP); Naoto NOMURA, Yamaguchi (JP)

(73) Assignee: TOKUYAMA CORPORATION, Yamaguchi (JP)

(21) Appl. No.: 18/235,120

(22) Filed: Aug. 17, 2023

(30) Foreign Application Priority Data
Aug. 18, 2022 (JP) 2022-130604
Nov. 2, 2022 (JP) 2022-176754

(51) Int. Cl. C09K 13/08; H01L 21/311

(52) U.S. Cl. CPC C09K 13/08; H01L 21/31111

(57) ABSTRACT

Provided is an etching solution for SiCN, the etching solution containing a fluorine-containing compound, an acid, and water, wherein a fluoride ion concentration is 0.3 mol/kg or more and 9 mol/kg or less, and a concentration of the acid is 55 mass % or more and 90 mass % or less.

### TECHNICAL FIELD

The present invention relates to an etching solution for selectively etching SiCN compared with Si. The present invention also relates to a method of manufacturing a silicon device using the etching solution. The present invention also relates to a method of treating a substrate using the etching solution. The substrate includes a semiconductor wafer or a silicon substrate.

### BACKGROUND ART

Various materials are used in manufacturing processes of semiconductor devices. Among those materials, SiN and SiCN are known to be useful in various fields, such as copper diffusion barrier films, passivation films, etch stop films, surface protective films, and gas barrier films. A SiN film (silicon nitride film) or a SiCN film (silicon carbonitride film) is formed on a substrate of a silicon wafer, its processed body, or the like, and used. Here, SiCN also includes compounds containing hydrogen and/or oxygen in addition to compounds having a skeleton of silicon, carbon, and nitrogen, for example, as shown in Non-Patent Document 1.

In the pattern formation of a semiconductor, a step of etching a SiN film and/or a SiCN film formed on a substrate selectively compared to Si may be necessary (hereinafter “selective” means being selective compared to Si unless otherwise stated).

A phosphoric acid aqueous solution is commonly used for etching SiN. However, unlike SiN, SiCN is hardly etched with a phosphoric acid aqueous solution. This is probably due to the difference in polarity between the Si—C bond and the Si—N bond. The difference in electronegativity between a C atom and a Si atom is smaller than that between a N atom and a Si atom. Thus, the polarization of the Si—C bond is smaller than that of the Si—N bond, and thus it is conceivable that an electrophilic addition reaction with an acid is less likely to occur and the etching of SiCN hardly proceeds.

For a method of etching SiCN, a method using a composition containing an oxidizing agent, a fluorine compound, and water has been proposed (Patent Document 1); however, the etching rate of SiCN described in Examples thereof is less than 250 Å/30 min, not providing a sufficient rate. In addition, for Si, Patent Document 1 also describes that an insulating film can be removed without damaging a substrate but does not describe the etching rate or surface roughness of Si.

### PRIOR ART DOCUMENTS

### Patent Document

Patent Document 1: JP 2007-049145 A

### Non-Patent Document

Non-Patent Document 1: ECS Journal of Solid State Science and Technology, 8 (6) P346-P350 (2019)

### SUMMARY OF INVENTION

### Technical Problem

In the manufacturing of semiconductor devices, the use of SiCN provides even better performance, but as described above, there has been no material having a sufficient etching rate of SiCN, capable of selectively etching SiCN compared to Si, and capable of preventing surface roughness of Si, and its use has been extremely limited. Thus, an object of the present invention is to provide an etching solution capable of selectively etching SiCN compared to Si and preventing surface roughness of Si.

### Solution to Problem

In view of the above problems, the present inventors have diligently studied a composition capable of selectively etching SiCN. As a result, the present inventors have found that further addition of a fluorine compound to an acid, such as a phosphoric acid aqueous solution and/or sulfuric acid, which has been used for etching SiN in the art, can greatly improve the etching rate of SiCN with little change in the etching rate of Si, and completed the present invention.

That is, the present invention is configured as follows.

Aspect 1. An etching solution for SiCN, the etching solution containing a fluorine-containing compound, an acid, and water, wherein
a fluoride ion concentration is 0.3 mol/kg or more and 9 mol/kg or less, and
a concentration of the acid is 55 mass % or more and 90 mass % or less.

Aspect 2. The etching solution according to aspect 1, wherein a boiling point of the acid is 105° C. or higher.

Aspect 3. The etching solution according to aspect 1 or 2, wherein the acid is at least one acid selected from phosphoric acid and sulfuric acid.

Aspect 4. The etching solution according to any one of aspects 1 to 3, wherein at least a part of fluorine-containing compound is a tetraalkylammonium fluoride having a total carbon number of 8 or less.

Aspect 5. A method of treating a substrate, the method comprising bringing the etching solution according to any one of aspects 1 to 4 into contact with a substrate having a Si surface and a SiCN surface to selectively etch the SiCN surface.

Aspect 6. The method of treating a substrate according to aspect 5, wherein the etching is performed in a range of 105° C. or higher and 180° C. or lower.

Aspect 7. The method of treating a substrate according to aspect 5 or 6, wherein the substrate is a substrate having no SiO₂ surface.

Aspect 8. A method of manufacturing a silicon device, the method including the method of treating a substrate according to any one of aspects 5 to 7 in a step.

### Effects of Invention

According to the present invention, SiCN can be selectively etched using a solution containing certain concentrations of an acid, a fluorine-containing compound, and water as an etching solution, and surface roughness of Si can be prevented.

### DESCRIPTION OF EMBODIMENTS

### (Etching Solution)

An etching solution according to an embodiment of the present invention includes a solution containing an acid, water, and a fluorine-containing compound and is used for etching silicon carbonitride (also described as SiCN). In addition, the etching solution according to an embodiment of the present invention can selectively etch SiCN compared to Si. In other words, the etching solution according to an embodiment of the present invention is an etching solution that selectively etches SiCN compared to Si. The “etching solution for SiCN” referred to in the present invention is a solution to be used for an etching target (e.g., such as a substrate) containing SiCN.

The acid in the etching solution according to an embodiment of the present invention is an essential component used for allowing the etching reaction of SiCN to proceed and preventing the etching of silicon (also described as Si). SiCN is etched at higher temperatures, and thus an acid with a boiling point of 105° C. or higher is preferably used.

The content of the acid contained in the etching solution is 55 mass % or more and 90 mass % or less. With too small an amount of the acid, the etching rate of SiCN would not be sufficient, and the etching rate of Si would increase, tending to reduce the selectivity ratio and increase the surface roughness of Si. Furthermore, etching SiCN at high temperatures provides a high etching rate and is advantageous, and the etching solution with a higher proportion of the acid can be used stably at higher temperatures. On the other hand, a fluorine-containing compound and water are essential for the etching solution according to an embodiment of the present invention; with the content of the acid more than 90 mass %, the blending amounts of the fluorine-containing compound and water would be reduced, and this would reduce the etching rate of SiCN. The content of the acid in the etching solution according to an embodiment of the present invention is preferably 57 mass % or more and 85 mass % or less and more preferably 60 mass % or more and 80 mass % or less. This concentration range is effective in that a sufficient etching rate of SiCN is achieved, and SiCN can be selectively etched by reducing the etching rate of Si and preventing the surface roughness of Si.

The acid preferably has a boiling point of 105° C. or higher (for a solid, a decomposition point of 105° C. or higher). This is because SiCN is etched at high temperatures of 105° C. or higher as described later. Specific examples of such an acid include one or more selected from the group consisting of phosphoric acid, sulfuric acid, nitric acid, hydrochloric acid, acetic acid, citric acid, boric acid, tetrafluoroboric acid, trifluoromethanesulfonic acid, fluorosulfonic acid, and methanesulfonic acid. One of these acids can be used alone, or a plurality of different types can be mixed and used.

Among the above acids, phosphoric acid and sulfuric acid have high boiling points, and high-purity products are manufactured and sold for semiconductor manufacturing. Thus, at least one selected from phosphoric acid and sulfuric acid is suitably used in the etching solution according to an embodiment of the present invention. The concentration of phosphoric acid when used alone is 55 mass % or more and 90 mass % or less, preferably 57 mass % or more and 85 mass % or less, and more preferably 60 mass % or more and 80 mass % or less. On the other hand, sulfuric acid is a stronger acid than phosphoric acid. Thus, many protons dissociate, and a sufficient effect can be achieved at a concentration lower than that of phosphoric acid. The concentration of sulfuric acid when used alone is 55 mass % or more and 90 mass % or less, preferably 55 mass % or more and 85 mass % or less, and more preferably 55 mass % or more and 80 mass % or less. In the present specification, when the blending amount of each component is described in mass %, the numerical value is a proportion to the entire etching solution regarded as 100 mass %.

Although a concentrated solution of phosphoric acid is in equilibrium between orthophosphoric acid (H₃PO₄) and polyphosphoric acid in the solution, the above content is an amount based on the assumption that the entire amount is present as orthophosphoric acid. The same applies to the case where phosphoric acid is present as pyrophosphoric acid or the like.

The etching solution according to an embodiment of the present invention contains a fluorine-containing compound as an essential component. The fluorine-containing compound is any substance that at least partially dissociates in the etching solution and can supply a fluoride ion (F⁻) into the solution. The presence of a fluoride ion in the etching solution promotes the cleavage of the Si—C bond contained in SiCN and greatly increases the etching rate of SiCN.

In the etching solution according to an embodiment of the present invention, the fluoride ion content is 0.3 mol/kg or more and 9 mol/kg or less. The etching solution with a fluoride ion content of less than 0.3 mol/kg would fail to provide a practically sufficient etching rate of SiCN. On the other hand, the etching solution with a higher fluoride ion content has a higher promoting effect on etching SiCN, but a fluoride ion content of more than 9 mol/kg would make it difficult to have sufficient blending amounts of phosphoric acid and water. The fluoride ion content in the etching solution according to an embodiment of the present invention is preferably 0.35 mol/kg or more and 7 mol/kg or less and more preferably 0.4 mol/kg or more and 5 mol/kg or less.

The fluoride ion concentration can be measured by ion chromatography or a method using a fluoride ion-selective electrode. When a compound that has a high dissociation constant and is considered to be almost completely dissociated is used as the fluorine-containing compound, the fluoride ion amount calculated from the blending amount can be directly regarded as the fluoride ion amount in the etching solution.

From the viewpoint of the efficiency of allowing fluoride ions to be present in the etching solution, a compound that is almost completely dissociated as described above is preferably used as the fluorine-containing compound. In addition, the etching solution according to an embodiment of the present invention preferably does not contain a metal as described later, and thus a metal fluoride, such as sodium fluoride, is preferably avoided.

Specific examples of such a fluorine-containing compound include ammonium fluoride, tetramethylammonium fluoride, ethyltrimethylammonium fluoride, diethyldimethylammonium fluoride, propyltrimethylammonium fluoride, butyltrimethylammonium fluoride, tetraethylammonium fluoride, tetrapropylammonium fluoride, and tetrabutylammonium fluoride. One of these fluorine-containing compounds can be used alone, or a plurality of different types can be mixed and used. When a plurality of these fluorine-containing compounds is mixed and used, those exemplified above can be freely combined.

Although the reason is unknown, the presence of a tetraalkylammonium ion having a total carbon number of 8 or less in the etching solution tends to increase the etching rate of SiCN. Thus, it is preferable that at least a part of fluorine-containing compound be a tetraalkylammonium fluoride having a total carbon number of 8 or less. Examples of those corresponding to the fluorine compound include tetramethylammonium fluoride, ethyltrimethylammonium fluoride, diethyldimethylammonium fluoride, propyltrimethylammonium fluoride, butyltrimethylammonium fluoride, and tetraethylammonium fluoride. Among them, a compound having a total carbon number of 6 or less and even more preferably 5 or less is more preferable.

The concentration of the tetraalkylammonium ion having a total carbon number of 8 or less is preferably 0.001 mol/kg or more and 5 mol/kg or less and more preferably 0.01 mol/kg or more and 3 mol/kg or less. With the concentration less than 0.001 mol/kg, the effect of improving the etching rate of SiCN would be difficult to achieve. On the other hand, a compound having a tetraalkylammonium ion is expensive, and using too much an amount of such a compound may lead to insufficient amounts of other components. Thus, the concentration is preferably 5 mol/kg or less.

It is preferable that at least a part of fluorine-containing compound be a tetraalkylammonium fluoride having a total carbon number of 8 or less. “At least a part of” as used herein means that the content of a tetraalkylammonium fluoride having a total carbon number of 8 or less can be 1 mol % or more and 1000 mol % or less, 5 mol % or more and 500 mol % or less, or 10 mol % or more and 100 mol % or less relative to the total amount of the fluorine-containing compound.

The etching solution with a higher fluoride ion content has a higher promoting effect on etching SiCN, and the presence of a tetraalkylammonium ion having a total carbon number of 8 or less tends to improve the etching rate of SiCN. In view of these points, it is preferable that ammonium fluoride, which has a small molecular weight, and a tetraalkylammonium fluoride having a total carbon number of 8 or less be used in combination as the fluorine-containing compound. When ammonium fluoride and a tetraalkylammonium fluoride having a total carbon number of 8 or less are used in combination, examples of the molar ratio include from 9000:1 to 1:4000, and the molar ratio can be from 90:1 to 1:40 or from 10:1 to 1:10.

The etching solution according to an embodiment of the present invention contains water as an essential component for the remainder. Without the presence of water, the reaction of etching of SiCN would not proceed. The content of water is 5 mass % or more and 43.8 mass % or less, preferably 10 mass % or more and 41.8 mass % or less, and more preferably 15 mass % or more and 38.5 mass % or less although this depends on the types and amounts of other components. The amount of water in this case is an amount based on the assumption that, when the etching solution contains the phosphoric acid, the phosphoric acid is present entirely as orthophosphoric acid.

The silicon etching solution according to an embodiment of the present invention can further contain a cerium compound. For example, one or more of cerium hydroxide, cerium salts, and double salts containing cerium and a cation other than cerium (e.g., an ammonium ion) can be used. The cerium compound is preferably cerium nitrate, cerium sulfate, cerium ammonium nitrate, cerium ammonium sulfate, or the like. These can be hydrates.

The silicon etching solution according to an embodiment of the present invention can further contain a nitrate compound. For example, one or more selected from the group consisting of nitrate salts and nitrite salts can be used. Preferable examples of the nitrate compound include one or more selected from the group consisting of ammonium nitrate and quaternary alkylammonium nitrates. The carbon number of the alkyl of the quaternary alkylammonium nitrate can be each independently from 1 to 5. Specific examples of the nitrate compound include one or more selected from the group consisting of ammonium nitrate, tetramethylammonium nitrate, tetraethylammonium nitrate, tetrapropylammonium nitrate, and tetrabutylammonium nitrate. The etching solution containing a nitrate compound can improve the etching rate of SiCN.

The etching solution according to an embodiment of the present invention can consist only of the acid, the fluorine-containing compound, and water described above, and can achieve a sufficient etching rate and selectivity with these three components. However, the etching solution can further contain a component, such as a surfactant, to the extent that the object of the present invention is not impaired. For the surfactant, any of a cationic surfactant, an anionic surfactant, a nonionic surfactant, and an amphoteric surfactant that do not decompose in the etching solution can be used. Such a surfactant improves the wettability of the silicon substrate surface to make the contact between the SiCN surface and the etching solution more uniform, thereby contributing to uniform etching of the SiCN surface.

The etching solution according to an embodiment of the present invention is a homogeneous acid solution in which all blended components are dissolved. Furthermore, to prevent contamination during etching, the number of particles with a size of 200 nm or greater contained in the etching solution according to an embodiment of the present invention is preferably 100/mL or less and more preferably 50/mL or less.

From the viewpoint of preventing contamination of an etching target, concentrations of metal impurities are also preferably as low as possible, and specifically, the concentrations of Ag, Al, Ba, Ca, Cd, Co, Cr, Cu, Fe, K, Li, Mg, Mn, Na, Ni, Pb, and Zn are all preferably 1 ppm or less and more preferably 1 ppb or less.

The etching solution according to an embodiment of the present invention can contain a composite salt, a decomposition product, an impurity, or the like derived from a blended component. For example, the etching solution blended with four components of phosphoric acid, ammonium fluoride, tetramethylammonium fluoride, and water can contain ammonium phosphate, tetramethylammonium phosphate, trimethylamine, hydrofluoric acid, and/or the like.

### (Manufacturing Method)

A method of manufacturing the etching solution according to an embodiment of the present invention is not particularly limited, and for example, the acid, the fluorine-containing compound, and water described above are mixed to predetermined concentrations, and dissolved to produce a homogeneous solution.

For the acid, a product with the lowest possible concentrations of a metal impurity and/or an insoluble impurity as described above is preferably used; a commercially available product is purified as necessary by recrystallization, column purification, ion exchange purification, distillation, sublimation, filtration treatment, or the like and can be used. In addition, for the phosphoric acid and sulfuric acid, a high-purity product manufactured and sold for semiconductor manufacturing is preferably used.

Also, for the fluorine-containing compound, a product with the highest possible purity is preferably used; a commercially available product is purified as necessary by recrystallization, column purification, ion exchange purification, filtration treatment, or the like and can be used. For ammonium fluoride, a high-purity product manufactured and sold for semiconductor manufacturing is preferably used. In addition, for tetramethylammonium fluoride, a high-purity product with a small impurity content can be produced, for example, by neutralizing a tetramethylammonium hydroxide (TMAH) aqueous solution with hydrofluoric acid, both of which are manufactured and sold for semiconductor manufacturing, and such a high-purity product is preferably used.

In the etching solution, water is contained for the remainder. Also, for the water, high-purity water with a small impurity content is preferably used. The impurity amount can be evaluated by electrical resistivity. Specifically, the electrical resistivity is preferably 0.1 Ml cm or greater, more preferably 15 MΩ·cm or greater, and particularly preferably 18 MΩ·cm or greater. Such water with a small impurity amount can be easily manufactured and/or obtained as ultrapure water for semiconductor manufacturing. Furthermore, ultrapure water also has a significantly small amount of an impurity that does not affect (or contributes little to) the electrical resistivity and thus is highly suitable.

In the manufacturing of the etching solution according to an embodiment of the present invention, after mixing and dissolving the components, the resulting solution is also preferably passed through a filter with openings of several nanometers to several tens of nanometers to remove particles. The process of passing the resulting solution through a filter can be performed multiple times as necessary. In addition to that, a process of various types known as a method of manufacturing a chemical solution for manufacturing a semiconductor can be applied.

### Application and Method of Use

The etching solution according to an embodiment of the present invention can be used in an etching treatment of a substrate having a SiCN surface in manufacturing a semiconductor device. A substrate having a SiCN surface is usually produced by forming a SiCN film on a substrate by a method, such as a chemical vapor deposition (CVD) method, a physical vapor deposition (PVD) method, or sublimation recrystallization. The etching solution according to an embodiment of the present invention can also etch any SiCN surface formed by a known method as described above. In addition, a SiCN film used in manufacturing a semiconductor device may contain hydrogen in an amount up to 133 atomic % relative to silicon depending on its manufacturing method. Such a film containing hydrogen also corresponds to SiCN to be etched in an embodiment of the present invention. Furthermore, SiCN to be etched in an embodiment of the present invention can contain an impurity element of various types (e.g., oxygen) to the extent that it is usually contained. The etching solution according to an embodiment of the present invention can also etch a SiC film and a SiC single crystal substrate and can be used for these substrates.

Moreover, the etching solution according to an embodiment of the present invention can be used for treating a substrate with a Si surface and a SiCN surface. Using the etching solution according to an embodiment of the present invention enables selective etching of a SiCN surface while preventing etching of a Si surface.

However, the etching solution according to an embodiment of the present invention contains a fluoride ion and thus also etches SiO₂ at a high speed. Striking a balance between etching SiCN and etching SiO₂ is usually difficult although this depends on the target etching amount (depth). Thus, the substrate with a Si surface and a SiCN surface preferably does not have a SiO₂ surface.

The etching solution according to an embodiment of the present invention is particularly effective when used in a treatment of selectively etching a SiCN surface portion from a substrate having a Si surface and a SiCN surface, which has been substantially impossible with an etching solution in the art.

A method of treating a substrate using the etching solution according to an embodiment of the present invention includes:
a substrate holding step of holding a substrate in a horizontal posture, and
an etching solution supplying step of supplying the etching solution according to an embodiment of the present invention to a main surface of the substrate while the substrate is rotated about a vertical rotation axis passing through a central portion of the substrate.

Another method of treating a substrate using the etching solution according to an embodiment of the present invention includes:
a substrate holding step of holding a plurality of substrates in an upright posture, and
a step of immersing the substrates in an upright posture in the etching solution according to an embodiment of the present invention stored in a treatment vessel. In a preferred embodiment of the present invention, the etching solution is used in manufacturing a semiconductor device including a step of selectively etching a SiCN surface portion by supplying the etching solution in etching a substrate with a SiCN surface, particularly a substrate with a Si surface and a SiCN surface.

The temperature of the silicon etching solution during etching using the etching solution according to an embodiment of the present invention is appropriately determined from a range of 105° C. or higher and 180° C. or lower in view of a desired etching rate, surface conditions after etching, productivity, and the like but is suitably in a range of 105° C. or higher and 170° C. or lower (however, at a boiling point or lower of the etching solution to be used). In etching SiN, a phosphoric acid aqueous solution has been used at a high temperature of 140° C. to 180° C. in the art. However, the etching solution according to an embodiment of the present invention can etch SiCN also at relatively low temperatures. At temperatures above 180° C., damage may occur to semiconductor materials other than SiCN, and at temperatures below 105° C., etching SiCN at an industrially satisfactory rate would be difficult. In the above temperature range, etching can be performed also at the boiling point of the etching solution, which is one of preferred embodiments for controlling the etching temperature to a constant temperature.

During etching using the etching solution according to an embodiment of the present invention, ultrasonic waves or the like can be used to promote etching.

When a residual impurity remains on the surface of a substrate after the substrate treating using the etching solution according to an embodiment of the present invention, a known treatment of various types can be applied to remove the impurity. For example, there is a method in which a rinse treatment is performed on a substrate using a rinse solution. For the rinse solution, a known rinse solution can be used, and examples include acidic aqueous solutions, such as hydrochloric acid, hydrofluoric acid, and sulfuric acid; alkaline aqueous solutions, such as ammonia water; a mixed solution of hydrofluoric acid and hydrogen peroxide solution (FPM); a mixed solution of sulfuric acid and hydrogen peroxide solution (SPM); a mixed solution of ammonia water and hydrogen peroxide solution (APM); and a mixed solution of hydrochloric acid and hydrogen peroxide solution (HPM). One of these can be used alone, or a plurality of these can be used in combination.

In the method of treating a substrate using the etching solution according to an embodiment of the present invention, the etching solution after treating can be collected on a wafer and can be used for treating another wafer after performing filter filtration and/or a regeneration process, such as concentration adjustment of components of the etching solution. The concentration adjustment of components can include a mechanism for additionally adding a fresh acid, water, and/or fluorine-containing compound while monitoring the concentrations of the acid, water, and the fluoride ion. In addition, water and/or a low-concentration acid diluted with water can be used to adjust a water content.

### (Method of Manufacturing Silicon Device)

A method of manufacturing a silicon device according to an embodiment of the present invention includes the method of treating a substrate described above as an etching step. For the etching step, the conditions described above can be applied as they are.

The method of manufacturing a silicon device can include a known step used in a method of manufacturing a silicon device, such as one or more steps selected from a wafer fabrication step, an oxide film formation step, a transistor formation step, a wiring formation step, and a chemical vapor deposition (CMP) step.

### EXAMPLES

Hereinafter, the present invention will be described in further detail by examples, but the present invention is not limited to these examples.

Experimental methods/evaluation methods in examples and comparative examples are as follows.

### (Method of Preparing Etching Solution)

Predetermined amounts of an acid, water, and a fluorine-containing compound were placed in a fluororesin flask, and the flask was immersed in an oil bath whose temperature was set to the same temperature as the boiling point of an etching solution (a predetermined temperature in Example 12) and heated for 30 minutes with stirring the solution at 600 rpm.

### (Method of Evaluating Etching Rate)

A silicon wafer (SiCN film) with a size of 2×1 cm on which a SiCN film was formed was prepared, and the initial film thickness was measured with a spectroscopic ellipsometer. The SiCN film was immersed in 300 g of the etching solution heated to the same temperature as the boiling point (a predetermined temperature in Example 12). The wafer was washed by a rinse treatment and dried, and then the film thickness was measured with a spectroscopic ellipsometer. The etching rate was determined by determining the etching amount of SiCN from the difference between the initial and post-treatment film thicknesses and dividing the etching amount by the etching time.

Also, for a silicon wafer (Si film) with a size of 2×1 cm on which a Si film was formed, the Si film was immersed, and the etching rate was calculated in the same manner as for the SiCN film.

From these measurement results, the etching rate ratio of the SiCN film to the Si film (SiCN/Si selectivity ratio) was determined.

The immersion time of the etching solution was 30 seconds for the SiCN film and 10 minutes for the Si film in Example 11, and 1 minute for the SiCN film and 10 minutes for the Si film in the other examples. The immersion time was 10 minutes for both the SiCN film and the Si film in comparative examples.

### Abbreviations

Fluorine-containing compounds used are abbreviated as follows in tables.
NH₄F: ammonium fluoride
TMAH: tetramethylammonium fluoride
ETMAF: ethyltrimethylammonium fluoride
TEAF: tetraethylammonium fluoride

### Example 1

In Example 1, an etching solution was prepared, in which ammonium fluoride was further blended as a fluorine-containing compound in addition to phosphoric acid and water. The specific composition is shown in Table 1.

Evaluation was performed by setting the etching temperature to 131° C., the boiling point of this composition, and the results are shown in Table 1. In this case, the etching rate of SiCN was high, and an excellent selectivity ratio (SiCN/Si, etching rate ratio) was exhibited.

### Example 2

In Example 2, evaluation was performed in the same manner as in Example 1 except that tetramethylammonium fluoride was used as a fluorine-containing compound in place of ammonium fluoride. The specific composition is shown in Table 1. The blending amount of the fluorine-containing compound was adjusted, and the fluoride ion amount was the same as that in Example 1.

The results are shown in Table 1. The etching rate of SiCN further improved than in Example 1. Thus, the selectivity ratio (SiCN/Si, etching rate ratio) was also good.

### Examples 3 to 5

In Examples 3 to 5, etching solutions were prepared using tetramethylammonium fluoride, ethyltrimethylammonium fluoride, and tetraethylammonium fluoride as a fluorine-containing compound, respectively. The specific compositions are shown in Table 1. The blending amounts of the fluorine-containing compounds were adjusted, and thus the fluoride ion amounts were the same as each other.

The results are shown in Table 1. Far superior etching rates were achieved in all these examples despite the lower etching temperature than that in Comparative Examples 1 to 3. Thus, the selectivity ratios (SiCN/Si, etching rate ratios) were also good.

### Comparative Example 1

In Comparative Example 1, an etching solution containing phosphoric acid and water, which has been used in the art for etching a silicon nitride (also described as SiN) film, was prepared without blending a fluorine-containing compound. The specific composition is shown in Table 1.

Evaluation was performed by setting the etching temperature to 131° C. the boiling point of this composition, and the results are shown in Table 1. SiCN was hardly etched with this composition.

### Comparative Examples 2 and 3

In Comparative Examples 2 and 3, etching solutions were prepared in which acetic acid or citric acid was further blended in addition to phosphoric acid and water. The etching solutions contain no fluorine-containing compound. Acetic acid and citric acid are silica deposition inhibitors, which have been blended in an etching solution for SiN containing phosphoric acid and water as main components in the art. The specific compositions are shown in Table 1.

The results of evaluation performed in the same manner as in Comparative Example 1 are shown in Table 1. Adding such an additive (citric acid or acetic acid) to the etching solution containing no fluorine-containing compound did not improve the etching rate of SiCN.

### Comparative Example 4

in Comparative Example 4, an etching solution was prepared, in which hydrofluoric acid was blended in addition to phosphoric acid and water. The specific composition is shown in Table 1.

Evaluation was performed by setting the etching temperature to 50° C., and the results are shown in Table 1. SiCN was hardly etched with this composition.

### Comparative Examples 5 and 6

In Comparative Examples 5 and 6, etching solutions were prepared, in which the content of tetramethylammonium fluoride was changed and the fluoride ion concentration was reduced. The specific compositions are shown in Table 1. Etching was performed at the etching temperature shown in Table 1. The etching rate of SiCN was lower with these compositions than with the etching rates of the examples.

TABLE 1

| | Etching solution composition | | | | | | | | |
|---|---|---|---|---|---|---|---|---|---|
| | Fluorine-containing compound or other | | | | | | | | |
| | additives | | | Phosphoric | | | SiCN | Si | |
| | | | Fluoride ion | acid | Water | Etching | etching | etching | SiCN/Si |
| | | Content | concentration | Content | Content | temperature | rate | rate | selectivity |
| | Type | (mass %) | (mol/kg) | (mass %) | (mass %) | (° C.) | (nm/min) | (nm/min) | ratio |
| Example 1 | NH₄F | 1.1 | 0.30 | 75 | 23.9 | 131 | 3.0 | <0.1 | >30 |
| Example 2 | TMAF | 2.8 | 0.30 | 75 | 22.2 | 131 | 3.4 | <0.1 | >34 |
| Example 3 | TMAF | 3.5 | 0.37 | 70 | 26.5 | 124 | 3.8 | <0.1 | >38 |
| Example 4 | ETMAF | 4.0 | 0.37 | 70 | 26.0 | 124 | 3.6 | <0.1 | >36 |
| Example 5 | TEAF | 5.5 | 0.37 | 70 | 24.5 | 124 | 3.4 | 0.13 | 26 |
| Comparative | — | 0 | 0 | 75 | 25.0 | 131 | 0.11 | <0.1 | >1 |
| Example 1 | | | | | | | | | |
| Comparative | Citric acid | 2.8 | 0 | 75 | 22.2 | 131 | <0.1 | <0.1 | N.D. |
| Example 2 | | | | | | | | | |
| Comparative | Acetic acid | 2.8 | 0 | 75 | 22.2 | 131 | 0.10 | <0.1 | >1 |
| Example 3 | | | | | | | | | |
| Comparative | Hydrofluoric | 10 | 5 | 10 | 80.0 | 50 | 0.34 | <0.1 | >3 |
| Example 4 | acid | | | | | | | | |
| Comparative | TMAF | 1.8 | 0.19 | 75 | 23.2 | 131 | 2.2 | <0.1 | >22 |
| Example 5 | | | | | | | | | |
| Comparative | TMAF | 1.8 | 0.19 | 70 | 28.2 | 123 | 1.8 | <0.1 | >18 |
| Example 6 | | | | | | | | | |

N.D.: not detected
—: none
<0.1: less than 0.1

### Example 6

In Example 6, evaluation was performed in the same manner as in Example 1 except that the blending amount of ammonium fluoride was increased. The specific composition is shown in Table 2.

The results are shown in Table 2. The etching rate of SiCN was further improved by increasing the fluoride ion amount.

### Example 7

In Example 7, ammonium fluoride and tetramethylammonium fluoride were used in combination as fluorine-containing compounds. Here, the fluoride ion amount was adjusted and thus was equivalent to that in Example 6. The specific composition is shown in Table 2.

The results are shown in Table 2. Despite the same fluoride ion amount, the combined use with tetramethylammonium fluoride improved the etching rate of SiCN more than in Example 6.

TABLE 2

| | Etching solution composition | | | | | | | | | |
|---|---|---|---|---|---|---|---|---|---|---|
| | Fluorine-containing compound | | | | Phosphoric | | | | | |
| | | | Fluoride ion | | acid | Water | Etching | SiCN | Si | SiCN/Si |
| | | Content | concentration | | Content | Content | temperature | etching rate | etching rate | selectivity |
| | Type | (mass %) | (mol/kg) | | (mass %) | (mass %) | (° C.) | (nm/min) | (nm/min) | ratio |
| Example 6 | NH₄F | 1.7 | 0.46 | | 75 | 23.3 | 131 | 5.3 | <0.1 | >53 |
| Example 7 | NH₄F | 1.0 | 0.27 | 0.46 | 75 | 22.2 | 131 | 5.7 | <0.1 | >57 |
| | TMAF | 1.8 | 0.19 | | | | | | | |

### Example 8

In Example 8, evaluation was performed in the same manner as in Example 7 except that the blending amount of ammonium fluoride was increased. The specific composition is shown in Table 3.

The results are shown in Table 3. The etching rate of SiCN was further improved by increasing the fluoride ion amount.

### Examples 9 and 10

In Examples 9 and 10, etching solutions similar to that of Example 8 were prepared except that the amount of phosphoric acid was reduced and the proportion of water was increased. The specific composition is shown in Table 3. The boiling point (i.e., etching temperature) of the etching solution also decreased by an amount corresponding to the decrease in the proportion of phosphoric acid.

The results are shown in Table 3. Although the etching rates tended to decrease as the treatment temperatures decreased, etching rates far superior to those of the comparative examples were still achieved.

Such a composition containing a small amount of phosphoric acid increases the time required for etching, but on the other hand, can reduce the amount of phosphoric acid, which is relatively expensive, and can also reduce the heating cost. Thus, the composition of the etching solution is to be adjusted according to which is given priority.

### Example 11

In Example 11, sulfuric acid was used as an acid, and both ammonium fluoride and tetramethylammonium fluoride were used in combination as fluorine-containing compounds. The specific composition is shown in Table 3.

The results are shown in Table 3. The use of sulfuric acid increased the boiling point, and that in turn improved the etching rate of SiCN.

### Example 12

In Example 12, evaluation was performed in the same manner as in Example 11 except that the etching temperature was set to 123° C., the temperature lower than the boiling point. In addition, the results are shown in Table 3. Although the etching rate tended to decrease as the treatment temperature decreased, an etching rate far superior to those of the comparative examples were still achieved.

TABLE 3

| | Etching solution composition | | | | | | | | | | |
|---|---|---|---|---|---|---|---|---|---|---|---|
| | Fluorine-containing compound | | | | Phosphoric | Sulfuric | | | | | |
| | | | Fluoride ion | | acid | acid | Water | Etching | SiCN | Si | SiCN/Si |
| | | Content | concentration | | Content | Content | Content | temperature | etching rate | etching rate | selectivity |
| | Type | (mass %) | (mol/kg) | | (mass %) | (mass %) | (mass %) | (° C.) | (nm/min) | (nm/min) | ratio |
| Example 8 | NH₄F | 3.4 | 0.92 | 1.11 | 75 | 0 | 19.8 | 131 | 13.1 | <0.1 | >131 |
| | TMAF | 1.8 | 0.19 | | | | | | | | |
| Example 9 | NH₄F | 3.4 | 0.92 | 1.11 | 69 | 0 | 25.8 | 123 | 10.7 | <0.1 | >107 |
| | TMAF | 1.8 | 0.19 | | | | | | | | |
| Example 10 | NH₄F | 3.4 | 0.92 | 1.11 | 59 | 0 | 35.8 | 107 | 5.8 | <0.1 | >58 |
| | TMAF | 1.8 | 0.19 | | | | | | | | |
| Example 11 | NH₄F | 2.3 | 0.63 | 0.73 | 0 | 69 | 27.8 | 158 | 25.3 | 0.51 | 50 |
| | TMAF | 0.9 | 0.10 | | | | | | | | |
| Example 12 | NH₄F | 2.3 | 0.63 | 0.73 | 0 | 69 | 27.8 | 123 | 5.1 | <0.1 | >51 |
| | TMAF | 0.9 | 0.10 | | | | | | | | |

### Example 13

An etching solution with the same composition as that of the etching solution of Example 7 was prepared using high-purity products for semiconductor manufacturing: 85% phosphoric acid, 40% ammonium fluoride, 25% tetramethylammonium hydroxide, and 50% hydrofluoric acid. In the preparation method, first, predetermined amounts of water and tetramethylammonium hydroxide were placed in a fluororesin flask, then hydrofluoric acid was added into the flask to neutralize the mixture, and an aqueous solution of tetramethylammonium fluoride was produced. Ammonium fluoride and phosphoric acid were further added, and then the mixture was heated and evaluated in the same manner as in other examples. The resulting etching rate was 5.8 nm/min for SiCN and less than 0.1 nm/min for Si, which were equivalent etching rates of SiCN and Si in Example 7.

1-8. (canceled)

9. An etching solution for SiCN, the etching solution comprising a fluorine-containing compound, an acid, and water, wherein
a fluoride ion concentration is 0.3 mol/kg or more and 9 mol/kg or less, and
a concentration of the acid is 55 mass % or more and 90 mass % or less.

10. The etching solution according to claim 9, wherein a boiling point of the acid is 105° C. or higher.

11. The etching solution according to claim 9, wherein the acid is at least one acid selected from phosphoric acid and sulfuric acid.

12. The etching solution according to claim 10, wherein the acid is at least one acid selected from phosphoric acid and sulfuric acid.

13. The etching solution according to claim 9, wherein at least a part of fluorine-containing compound is a tetraalkylammonium fluoride having a total carbon number of 8 or less.

14. The etching solution according to claim 10, wherein at least a part of fluorine-containing compound is a tetraalkylammonium fluoride having a total carbon number of 8 or less.

15. The etching solution according to claim 11, wherein at least a part of fluorine-containing compound is a tetraalkylammonium fluoride having a total carbon number of 8 or less.

16. A method of treating a substrate, the method comprising bringing the etching solution according to claim 9 into contact with a substrate having a Si surface and a SiCN surface to selectively etch the SiCN surface.

17. The method of treating a substrate according to claim 16, wherein the etching is performed in a range of 105° C. or higher and 180° C. or lower.

18. The method of treating a substrate according to claim 16, wherein the substrate is a substrate having no SiO₂ surface.

19. The method of treating a substrate according to claim 17, wherein the substrate is a substrate having no SiO₂ surface.

20. A method of manufacturing a silicon device, the method comprising the method of treating a substrate according to claim 16 in a step.

21. A method of manufacturing a silicon device, the method comprising the method of treating a substrate according to claim 17 in a step.

22. A method of manufacturing a silicon device, the method comprising the method of treating a substrate according to claim 18 in a step.

23. A method of manufacturing a silicon device, the method comprising the method of treating a substrate according to claim 19 in a step.
